(19) United States
(12) Patent Application Publication
(10) Pub. No.: US 2025/0149100 A1
(43) Pub. Date: May 8, 2025

(54) SEMICONDUCTOR NONVOLATILE MEMORY DEVICE

(71) Applicant: Renesas Electronics Corporation, Tokyo (JP)

(72) Inventors: Junichi SUZUKI, Tokyo (JP); Atsunori MIKI, Tokyo (JP)

(21) Appl. No.: 18/938,668

(22) Filed: Nov. 6, 2024

(30) Foreign Application Priority Data
Nov. 8, 2023 (JP) 2023-190734

(51) Int. Cl. G11C 16/34; G11C 16/10; G11C 16/24

(52) U.S. Cl. CPC G11C 16/3459; G11C 16/102; G11C 16/24

(57) ABSTRACT

A semiconductor nonvolatile memory device or the like capable of narrowing a cell voltage distribution range while suppressing write delay is provided. The semiconductor nonvolatile memory device includes: a plurality of gate lines; a plurality of bit lines intersecting the plurality of gate lines; and a plurality of memory cells connected to respectively intersection points between the gate lines and the bit lines. The plurality of memory cells are connected to one gate line selected from among the plurality of gate lines respectively via the different bit lines, and the semiconductor nonvolatile memory device further includes a plurality of write bit line current or voltage control circuits respectively controlling bit line currents in order to simultaneously perform writing into the plurality of memory cells.

### CROSS-REFERENCE TO RELATED APPLICATION

The disclosure of Japanese Patent Application No. 2023-190734 filed on Nov. 8, 2023, including the specification, drawings and abstract is incorporated herein by reference in its entirety.

### BACKGROUND

The present disclosure relates to a semiconductor nonvolatile memory device.

A flash memory is a nonvolatile memory that performs data recording by storing electrons into a floating gate while using a semiconductor element that is called floating gate MOSFET (metal oxide semiconductor field effect transistor).

Attention is paid to “multi-bit (value) technique” for achieving an increase in capacity of the flash memory. In general multi-bit writing, the writing is simultaneously performed into a large number of cells on the same row. Since each of the memory cells has a physical variation, its cell voltage may have a write distribution range. In a multiple level cell (MLC) or the like, it is also important to control the write distribution range from the viewpoint of reliability or the like.

A method for controlling a writing speed by gradually increasing a gate voltage is a main trend. This is because, for example, the method rises Vtm along the gate voltage if the other condition is the same, is easier to perform the control than that in SL/BL due to the less load current, and is easier to perform the control due to its large voltage range.

There is disclosed technique listed below.

[Patent Document 1] Japanese Unexamined Patent Application Publication No. 2023-92938

### SUMMARY

However, in the related art, for example, decrease in a rise range of a pulse voltage for narrowing a distribution range of a writing middle level of the multiple level cell (MLC) or the like makes a problem that is delay of a writing time because of insufficiency of an operation margin (i.e., write/erase window).

The present disclosure has been made to solve such a problem, and its objective is to provide a semiconductor nonvolatile memory device or the like capable of narrowing a distribution range of a cell voltage while suppressing a writing delay.

Other objects and novel characteristics will be apparent from the description of the present specification and the accompanying drawings.

In a semiconductor nonvolatile memory device according to one embodiment including: a plurality of gate lines; a plurality of bit lines respectively intersecting the plurality of gate lines; and a plurality of memory cells connected to respectively intersection points between the gate lines and the bit lines, the plurality of memory cells are connected to one gate line selected from among the plurality of gate lines respectively via the different bit lines, and the semiconductor nonvolatile memory device further includes a plurality of write bit line current or voltage control circuits respectively controlling bit line currents in order to simultaneously perform writing into the plurality of memory cells.

According to one embodiment, a semiconductor nonvolatile memory device or the like capable of narrowing a cell voltage distribution range while suppressing writing delay can be provided.

### BRIEF DESCRIPTIONS OF THE DRAWINGS

FIG. 1 is a distribution diagram of a cell current for explaining a data writing operation based on a reference current type of a flash memory;

FIG. 2 is a diagram illustrating a cell cross-sectional structure of a typical memory chip;

FIG. 3 is a diagram for explaining general multi-bit writing;

FIG. 4 is a circuit diagram for explaining general multi-bit writing;

FIG. 5 is a graph for explaining general multi-bit writing;

FIG. 6 is a graph for explaining general multi-bit writing;

FIG. 7 is a circuit diagram for explaining multi-bit writing according to an embodiment;

FIG. 8 is a graph for explaining multi-bit writing according to the embodiment;

FIG. 9 is a diagram for explaining an electronic device including a semiconductor nonvolatile memory device according to the present embodiment;

FIG. 10 is a circuit diagram including a write bit line current control circuit according to the present embodiment;

FIG. 11 is a circuit diagram illustrating details of the write bit line current control circuit according to the present embodiment;

FIG. 12 is a graph for explaining a writing operation in an initial stage of writing;

FIG. 13 is a circuit diagram for explaining the writing operation in the initial stage of writing;

FIG. 14 is a graph for explaining a writing operation in a middle stage of writing;

FIG. 15 is a circuit diagram for explaining the writing operation in the middle stage of writing;

FIG. 16 is a graph for explaining a writing operation in a final stage of writing;

FIG. 17 is a circuit diagram for explaining the writing operation in the final stage of writing;

FIG. 18 is a flowchart of distribution-narrowed writing according to the present embodiment;

FIG. 19 is a diagram for explaining general multi-bit writing according to another embodiment;

FIG. 20 is a graph for explaining a writing operation according to another embodiment;

FIG. 21 is a circuit diagram for explaining the writing operation according to another embodiment;

FIG. 22 is a circuit diagram for explaining a writing operation according to another embodiment; and

FIG. 23 is a circuit diagram including a write bit line voltage control circuit according to another embodiment.

### DETAILED DESCRIPTION

For clarity of explanation, the following description and drawings are appropriately omitted and simplified. In the drawings, the same elements are denoted by the same reference sign, and the repetitive explanation thereof is omitted as needed.

First, outline of a flash memory will be explained. The flash memory is a storage medium in which data is readable and writable, and has various types ranging from a built-in type to a portable type. As the types of the flash memory, a USB memory, an SD card, a memory card, a memory stick, and a solid state drive (SSD) and the like are exemplified. The types of the flash memory are classified into a NAND type and an NOR type depending on a difference in electrical circuit structure. The flash memory includes several billions of cells or more, and each of the cells stores data “0” or “1”. The smaller a cell size is, and besides, the more the cells included in a memory chip is, the larger a capacity of the storage medium is.

When a threshold voltage (Vt) is negative in an erase state where charges are discharged from its floating gate, the stored data in the memory cell in the flash memory is “1”. On the other hand, in the erase state, when a writing operation for supplying the charges into the floating gate is performed, the memory cell becomes in a write state. When the threshold voltage (Vt) is positive in the write state, the stored data in the memory cell is “0”. That is, the threshold voltage (Vt) in the erase state of the memory cell made of a field effect transistor is lower than the threshold voltage in the write state thereof.

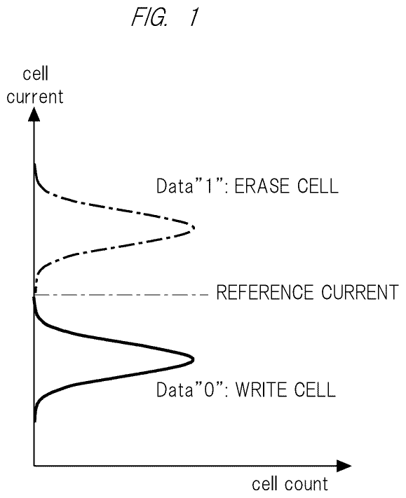

The memory cell as a reading target generates a cell current (also referred to as a source-drain current) dependent on the threshold voltage when a read voltage (positive voltage) is input to its gate. In the same memory cell, the cell current in the erase state is larger than the cell current in the write state that is the rise of the threshold voltage by the supply of the charges (see FIG. 1). A sense amplifier compares a reference current with the cell current, to read out data “1” or “0”.

FIG. 1 is a distribution diagram of the cell current for explaining a data writing operation based on a reference current type of the flash memory. FIG. 1 illustrates a cell current distribution curve in a case where the stored data in the whole of a plurality of memory cells configuring the nonvolatile memory device is “0” and a cell current distribution curve in a case where the stored data therein is “1”. The cell current distribution curve in the case where the stored data is “1” is also referred to as an erase cell distribution curve, and the cell current distribution curve in the case where the stored data is “0” is also referred to as a write cell distribution curve. In the reference current reading type, a reference current needs to be set in a current region where the erase cell distribution curve and the write cell distribution curve do not overlap each This is because the stored data may be erroneously other. verified by occurrence of a current region where the erase cell distribution curve and the write cell distribution curve overlap each other.

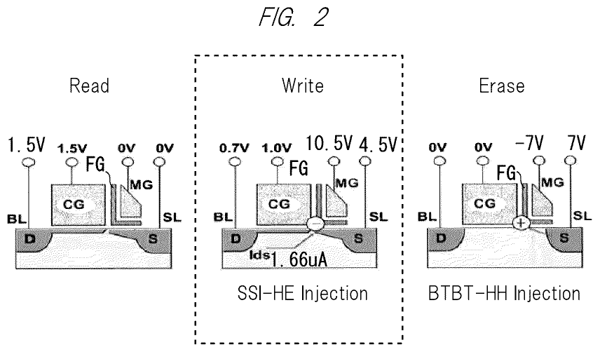

FIG. 2 is a diagram illustrating a cell cross-sectional structure of a typical memory chip. FIG. 2 is a diagram for explaining respective normal potential arrangements at the time of reading, writing, and erasing. A cell includes a transistor structure made of an n-type semiconductor and a p-type semiconductor, a gate structure, and a tunnel oxide film sandwiched between the transistor structure and the gate structure. The gate structure includes a control gate (CG), a floating gate (FG), and a memory gate (MG).

At the time of the normal writing, when SSI (Source Side Injection) writing is performed in, for example, an FMONOS (Flash Metal Oxide Nitride Oxide Semiconductor) cell, the writing is performed in a potential arrangement as illustrated in a middle diagram of FIG. 2. That is, an MG voltage is set to a high voltage (such as 10.5 V), and a CG voltage is set to 1.0 V. A source voltage is set to 4.5 V, and a drain voltage is set to 0.7 V. Due to the potential arrangement, electrons that have flowed out of a source (S) are stored in the floating gate FG after passing through the tunnel oxide film. Thus, since the threshold voltage (Vt) in the write state is positive, the stored data is “0”. In the MLC (multiple level cell) or the like, it may be desirable to more finely control the writing (by gradually changing the MG voltage) due to a request for reliability.

On the other hand, at the time of the data erasing, the drain voltage is set to 0 V, and the source voltage is set to 7 V. The MG voltage is set to −7 V. Holes are generated in the vicinity of the source by the high voltage applied to the source because of the band-to-band tunneling effect, and the holes are drawn into the floating gate FG by the negative voltage of the MG to cancel the electrons in the floating gate FG.

At the time of the reading, the MG voltage is set to 0 V, and the CG voltage is set to a low voltage (1.5 V). The drain voltage is set to 1.5 V. As a result, a current flowing from the source to the drain is detected. When the electrons are stored in the floating gate FG, the current is difficult to flow. Accordingly, the stored data is detected as “0”. On the other hand, when no electrons exist in the floating gate FG, the current easily flows. Accordingly, the stored data is detected as “1”.

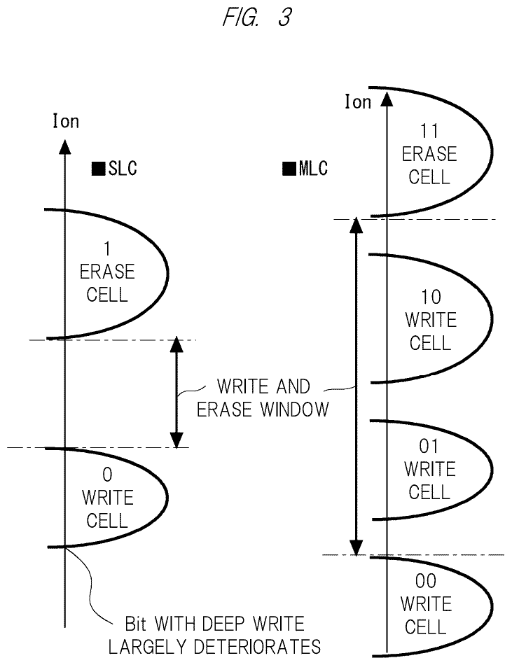

FIG. 3 is a diagram for explaining the general multi-bit writing. A vertical axis represents a drain current “Ion” flowing between the source and the drain illustrated in FIG. 2. A left diagram of FIG. 3 illustrates a cell distribution in a single level cell (SLC), and a right diagram of FIG. 3 illustrates a cell distribution in the multiple level cell (MLC).

The single level cell (SLC) is one of NAND-type flash memory systems, and is a system for storing 1-bit data made of binary values into one storage element (memory cell). In a case of a “1” erase cell, no electrons are stored in the floating gate FG. Accordingly, a relatively high current is flown. In a case of a “0” write cell, the electrons are stored in the floating gate FG. Accordingly, a relatively low current is flown. In the SLC, from a relationship between a minimum value of the cell current in the erase cell distribution curve and a maximum value of the cell current in the write cell distribution curve, respective write and erase ranges are determined, and reliability of the number of times of writing or the like is determined. Even in the SLC, the memory cell is largely deteriorated by the too deep write cell. Accordingly, it may be desirable to narrow the write distribution range in order to prevent the cell deterioration.

On the other hand, the multiple level cell (MLC) is a system for storing multi-bit data made of ternary values into one storage element (memory cell). An example illustrated in FIG. 3 includes four distributions. The MLC can store four states “00”, “01”, “10”, and “11” (that is, two bits). Specifically, in a “00” erase cell, no electrons are stored in the floating gate FG. Accordingly, a relatively high current is flown. On the other hand, in a “10” write cell, a “01” write cell, and a “00” write cell, the electrons stored in the floating gate FG are gradual in this order. Accordingly, a relatively low current is flown. In the MLC, write and erase window of the cell is increased by increase in a cell Vt distribution between the “00” write cell and the “11” erase cell. Therefore, reliability and operation problems increase. Some embodiments may employ a quad level cell (QLC) and a triple level cell (TLC) for the multi-bit writing, and the present disclosure is applicable.

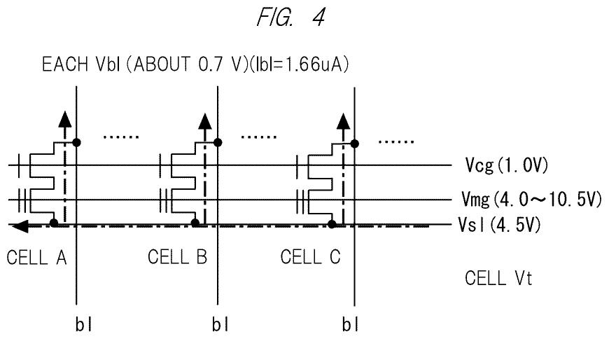

FIG. 4 is a circuit diagram for explaining the general multi-bit writing. Terms “Vcg” and “Vsl” respectively represent fixed potentials. In this example, Vcg is 1.0 V, and Vsl is 4.5 V. A potential “Vmg” is variable, and can be gradually increased from 4.0 V to 10.5 V by a voltage source. Each Vol is about 0.7 V, and Ibl is 1.66 μA.

For example, in the SLC, the data in the write cell is set to “0”, and the data not to be written (to remain erased) is set to “1”. The control for the writing of the data “0” or “1” is performed by a bit line write current. When the writing is performed into all cells (cells A, B, and C), the bit line current is caused to flow through all the cells as illustrated in FIG. 4. In this case, a bit line voltage is roughly about 0.7 V. On the other hand, when the writing is not performed into the individual cell, the bit line current in the individual cell is stopped.

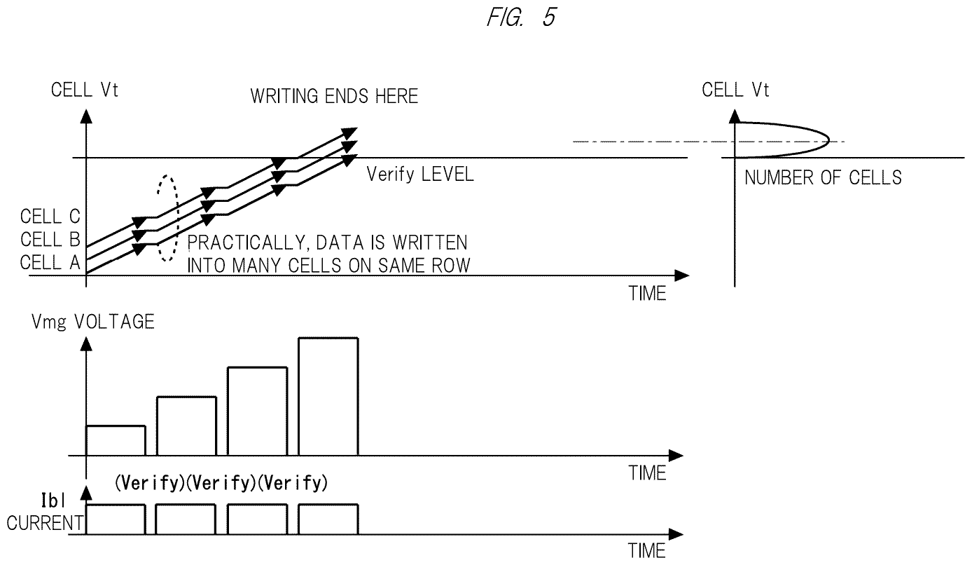

FIG. 5 is a graph for explaining the general multi-bit writing. As illustrated in FIG. 4, the writing operation is performed into the plurality of cells (cells A, B, and C) by applying a predetermined Vmg pulse voltage and a predetermined write bit line current Ibl to the target memory cell. The larger the stored amount of the electrons in the floating gate FG is, the higher the cell voltage Vt is gradually. Note that the cell voltage Vt is a lower limit of a voltage of a gate through which a drain current flows, and is also referred to as a “threshold voltage”. Then, when the Vmg voltage (or a reference current) is applied to each of the cells (cells A, B, and C) to perform reading, it can be verified whether or not the writing has been ended for each of the cells, depending on whether or not the drain current corresponding to a cell Vt verify level flows. This system is referred to as verifying. Therefore, it can be verified for each of the cells whether or not the cell voltage exceeds a target cell voltage Vt verify level. In FIG. 5, a verify period indicated as (Verify) is illustrated between the Vmg pulse voltages. If the cell voltage Vt does not reach the verify level, the Vmg pulse voltage is raised by a predetermined amount and is applied, and then, a verify operation is performed, and it is verified whether or not the cell voltage Vt reaches a verify level representing an end of the writing. Thus, the multi-bit writing is performed by the gradual raising of the Vmg pulse voltage, and then, the repetition of the verify operation as described above.

In the MLC, note that the same write level (such as “10”) may be written into all the cells (cells A, B, and C). In this case, as illustrated in FIG. 5, the verify level representing the end of the writing is the same among all the cells (cells A, B, and C). A different write level may be written into the cells (cells A, B, and C) (such as “10”, “01”, and “00” may be respectively written into the cells A, B, and C). In this case, the verify level representing the end of the writing may be different among the cells (cells A, B, and C).

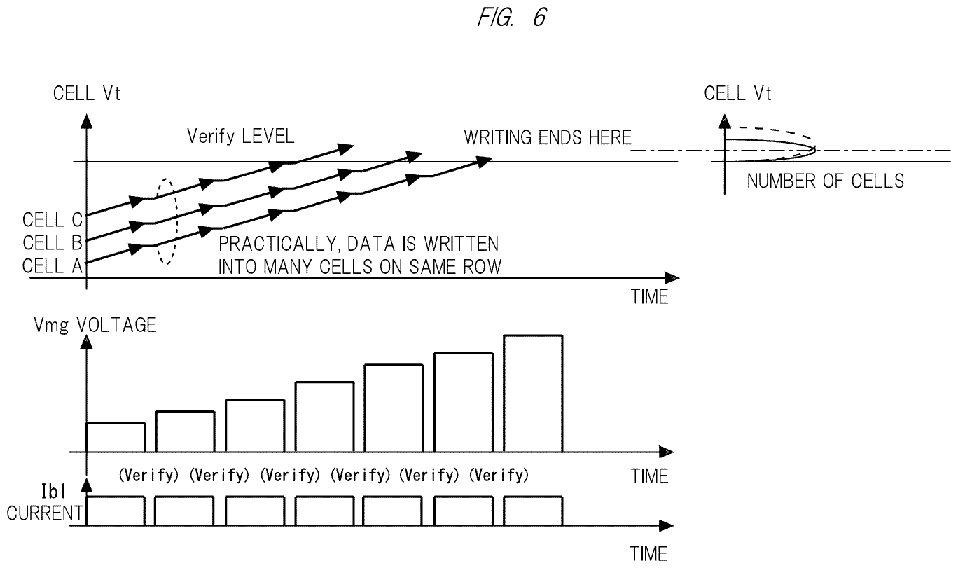

As illustrated in FIG. 6, in order to decrease the cell Vt distribution, a rise range of the Vmg pulse voltage needs to be However, as a result, the respective numbers of decreased. repetitions of the writing and the retry increase, and it takes a while until the cell voltage Vt (of the cell (the cell A in FIG. 6) into which the writing has finally been performed) reaches the verify level, and the multi-bit writing is delayed.

Generally, in the multi-bit writing, the writing is simultaneously performed into a large number of cells on the same word line. Since a writing speed and an initial position of each of the cells vary, its cell voltage Vt has a predetermined distribution range. The writing is ended sequentially from a cell in which its cell voltage Vt reaches the verify level among the large number of cells into which the writing is simultaneously performed. Particularly, in order to decrease the cell Vt distribution, when the rise range of the Vmg pulse voltage is decreased, the cell (the cell A in FIG. 6) into which the writing is finally performed among the large number of cells into which the writing is simultaneously performed is significantly delayed.

The deterioration of the memory cell can be suppressed by decreasing the distribution range of the cell voltage Vt, and an amount of information can be increased by storing a large number of bits in a memory.

As described above, in the related art, an operation margin (write and erase window) is insufficient, and therefore, there is a problem that the writing time is delayed by the narrowed distribution range of the writing middle level of the MLC.

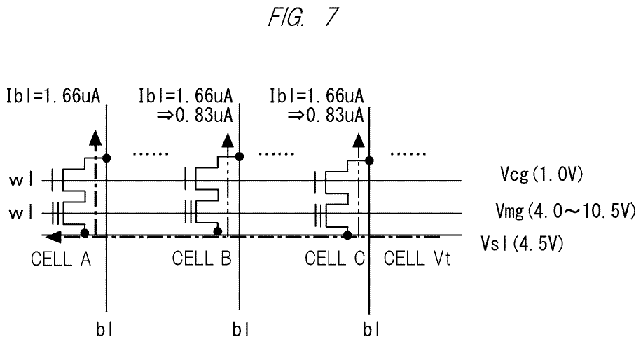

FIG. 7 is a circuit diagram for explaining the multi-bit writing according to an embodiment. In the present embodiment, the current flowing through each of bit lines bl is controlled at a plurality of levels (two levels that are 1.66 μA or 0.83 μA in this example). The Vmg voltage is common among word lines w1 in a row direction. Accordingly, a different voltage cannot be applied to each of the cells (cells A, B, and C in FIG. 7). Accordingly, in the present embodiment, the adjustment of the current flowing through each of the bit lines bl at the plurality of levels allows the different voltage to be applied to the cells (the cells A, B, and C in FIG. 7). Thus, in the MLC, the current Ibl is decreased in a cell other than the cell having the cell voltage Vt exceeding the verify level representing the end of the writing, and the writing speed is decreased in the cell. As a result, the write distribution range of the cell voltage can be narrowed.

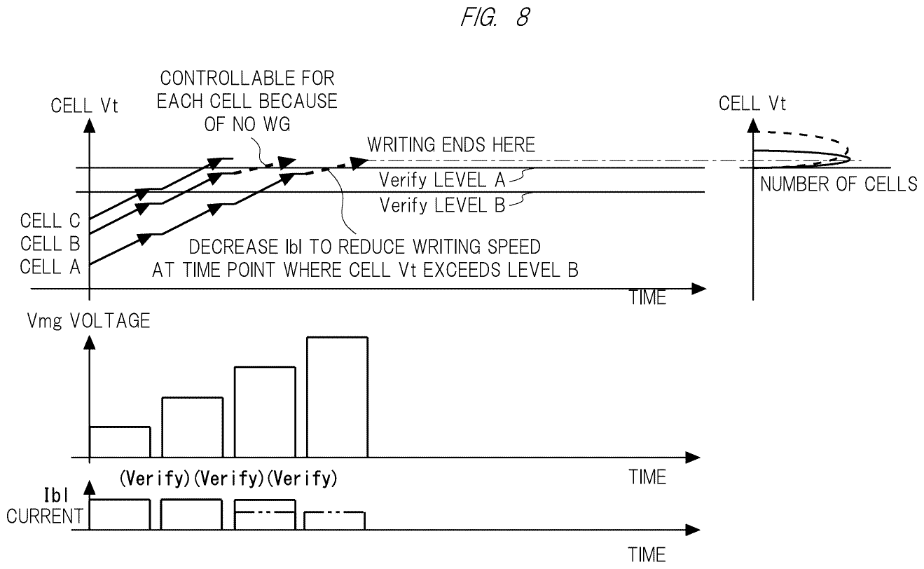

FIG. 8 is a graph for explaining the multi-bit writing according to the embodiment. In the present embodiment, a different verify level (that is a verify level B in FIG. 8) is prepared to be lower than the cell voltage Vt verify level (that is the verify level A in FIG. 8) representing the end of the writing. The verify level B is used to control the current Ibl flowing through each bit line bl. Specifically, the Vmg voltage (or reference current) corresponding to the verify level A or B of the cell voltage Vt is previously determined. When the previously-determined Vmg voltage (or reference current) is applied to perform the reading, it can be verified whether or not the cell voltage Vt exceeds a target cell Vt level. That is, if current value data corresponding to the verify level A or B can be read out by the application of the cell voltage corresponding to the verify level A or B, it can be verified that the cell voltage Vt exceeds the target cell voltage Vt level. On the other hand, if the current value data corresponding to the verify level A or B cannot be read out by the application of the cell voltage corresponding to the verify level A or B, it can be verified that the cell voltage Vt does not exceed the target cell voltage Vt level.

After the Vmg pulse voltage is gradually increased to reach a Vmg pulse voltage at which the cell voltage Vt reaches the verify level B, the cell voltage is applied to the corresponding cell to perform the data reading. If the desired current value data can be read out, the current Ibl is decreased (from 1.66 μA to 0.83 μA). Thus, the writing speed is decreased, and the distribution range of the cell voltage can be narrowed. For example, if the distribution range is desired to be halved, a writing speed at the end is halved, and the number of times of the writing is incremented by one at a maximum. However, the number of times of the retry is several tens (20 or more in this design) as a whole. Accordingly, this increment does not make a significant difference. That is, the delay of the writing time in the MLC can be suppressed while the distribution range is narrowed. The writing speed at this time is changed by the bit line current Ibl. In the bit lines, the level adjustment at so many stages is not achieved. However, the current can be roughly controlled in a case of a resolution of about a low single-digit level order. The current can be controlled for each of the bit lines. Accordingly, the writing does not need to be performed from the beginning again.

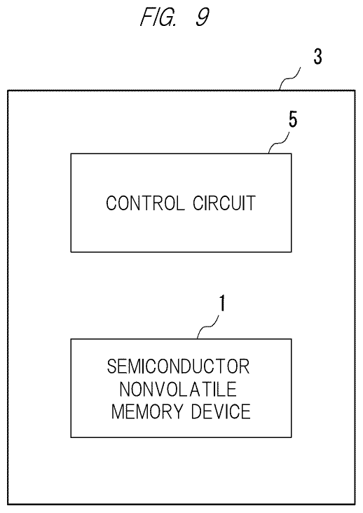

FIG. 9 illustrates an electronic device 3 including a semiconductor nonvolatile memory device 1. The electronic device 3 includes at least one control circuit 5 that controls an operation of the entire circuit. A processing circuit in the control circuit 5 can be based on one or more microprocessors, application processors, microcontrollers, digital signal processors, baseband processors, power management units, audio chips, specific-use integrated circuits, or the like. Specifically, the processing circuit can control a Y selector described later, instruct a gate driver circuit in a write bit line current or voltage control circuit (about a write Flag 1 or 2), and control a voltage source, or the like. The control circuit can be used to execute software such as an operating system or an application on the device.

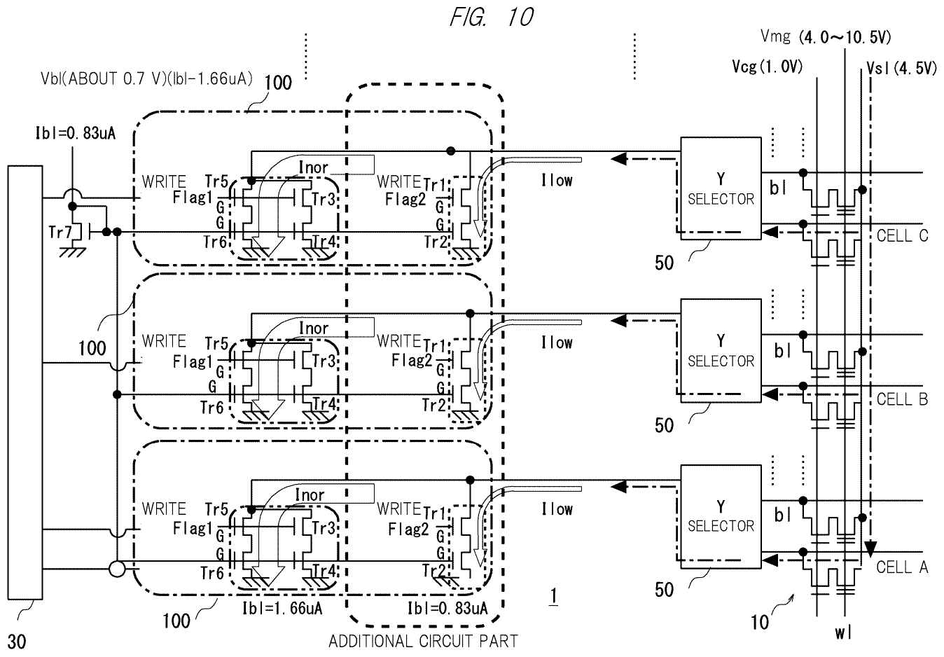

FIG. 10 is a circuit diagram illustrating the memory device according to the embodiment. The semiconductor nonvolatile memory device 1 that is a flash memory includes a memory cell array 10, a plurality of Y selectors 50, a plurality of write bit line current control circuits 100, and a gate driver circuit 30. The write bit line current control circuits 100 are provided to respectively correspond to the Y selectors 50.

The Y selector 50 receives (from the control circuit 5) a bit line address signal input from outside, and selects one write or read bit line from among a plurality of write and read bit lines. The write bit line current control circuit 100 controls the write bit line current to be supplied to the bit line selected by the Y selector 50. The gate driver circuit 30 is configured to turn on the write Flag 1 or the write Flag 2 into each of transistors in the write bit line current control circuit 100.

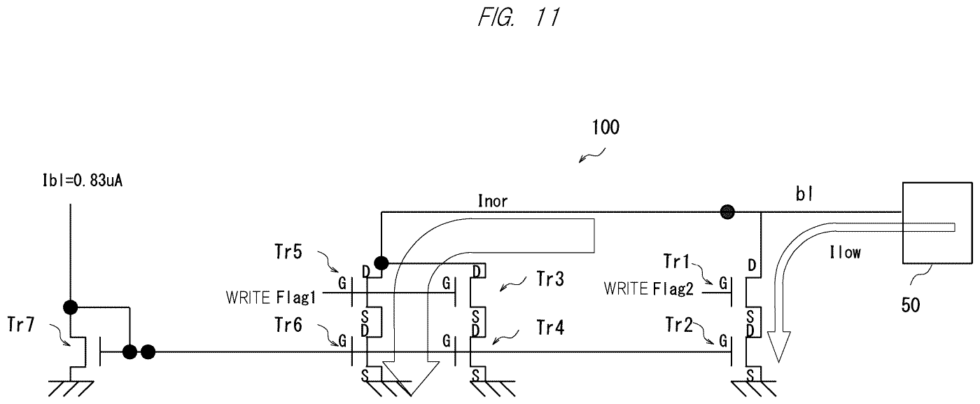

FIG. 11 is an enlarged diagram of the write bit line current control circuit 100. The bit line bl coupled to the Y selector 50 is connected to transistors Tr3 and Tr4 used for a current (“Inor” in FIG. 11) at the time of the normal writing. The bit line bl coupled to the Y selector 50 is connected to transistors Tr5 and Tr6 for a current at the time of the normal writing. The transistors Tr3 and Tr4 and the transistors Tr5 and Tr6 are connected in parallel to each other. A gate electrode of the transistor Tr3 and a gate electrode of the transistor Tr5 are connected to each other. When the gate voltage exceeding the threshold voltage is applied as the write Flag 1 at the time of the normal writing, the normal write current Inor (Ibl=1.66 μA) flows through the transistors Tr3 and Tr4 and the transistors Tr5 ad Tr6.

On the other hand, the bit line bl coupled to the Y selector 50 is connected to transistors Tr1 and Tr2 used for a current (“Ilow” in FIG. 11) at the time of the low-speed writing. When the gate voltage exceeding the threshold voltage is applied as the write Flag 2 at the time of the low-speed writing, a low-speed write current Ilow (Ibl=0.83 μA) flows through the transistors Tr1 and Tr2. The low-speed write current Ilow (Ibl=0.83 μA) can be halved of the normal write current Inor (Ibl=1.66 μA).

Although not illustrated in FIG. 10, a voltage source for gradually raising and applying the Vmg voltage is provided. The gate driver circuit 30 can be mounted as a part of the integrated circuit. Each Vbl is about 0.7 V, and the Ibl is 1.66 μA. The gate line of each of the transistors Tr2 and Tr6 in each of the write bit line current control circuits 100 is connected to a transistor Tr7.

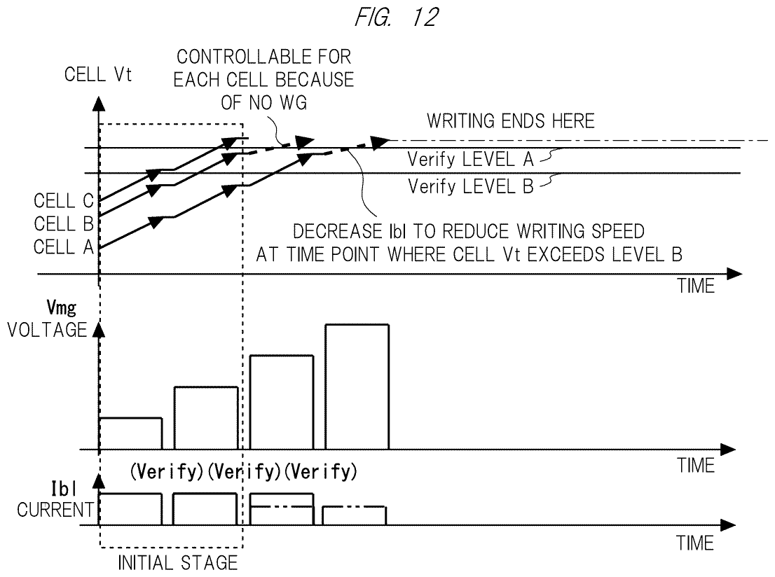

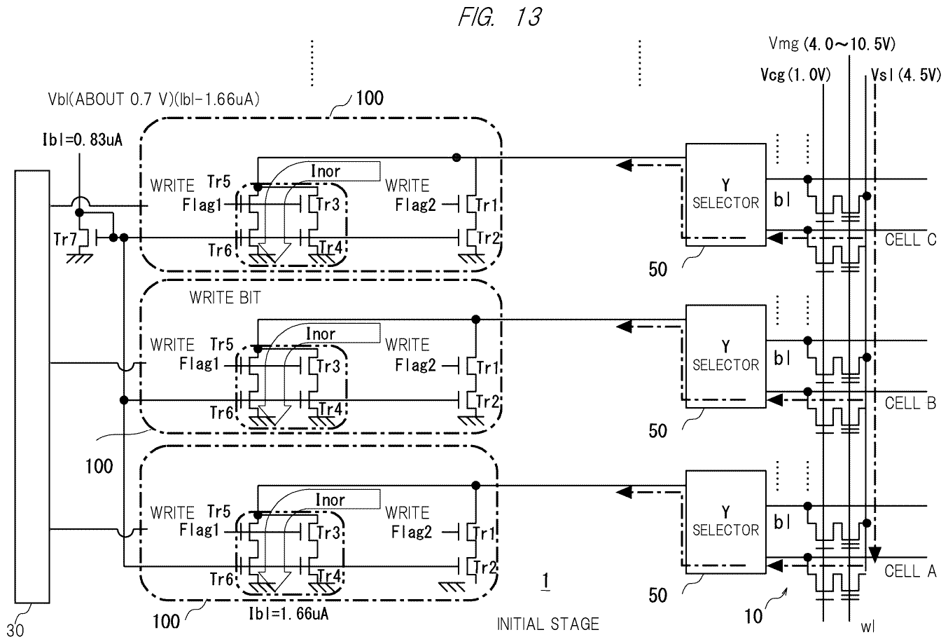

FIG. 12 is a graph for explaining a writing operation at an initial stage of the writing, and FIG. 13 is a circuit diagram for explaining the writing operation at the initial stage of the writing. At the initial stage of the writing (i.e., until the cell voltage Vt exceeds the verify level B), while the Vmg voltage is gradually raised, the writing is performed into cells at the Ibl current (i.e., 1.66 μA) using the current source at the time of the normal writing. As illustrated in the circuit diagram of FIG. 13, for all cells A, B, and C, each of the write bit line current control circuits 100 performs control to make flow of the normal write current Inor (Ibl=1.66 μA) through the transistors Tr3 and Tr4 and the transistors Tr5 and Tr6 when the gate voltage exceeding the threshold voltage is applied thereto as the write Flag 1 at the time of the normal writing.

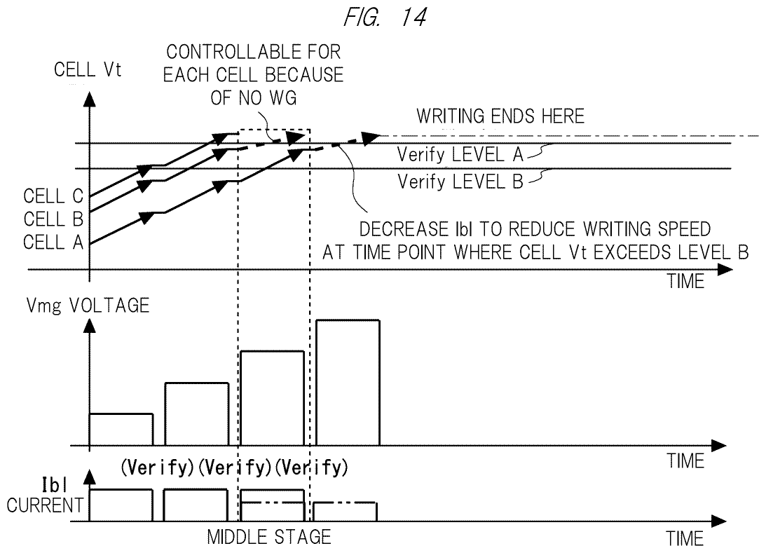

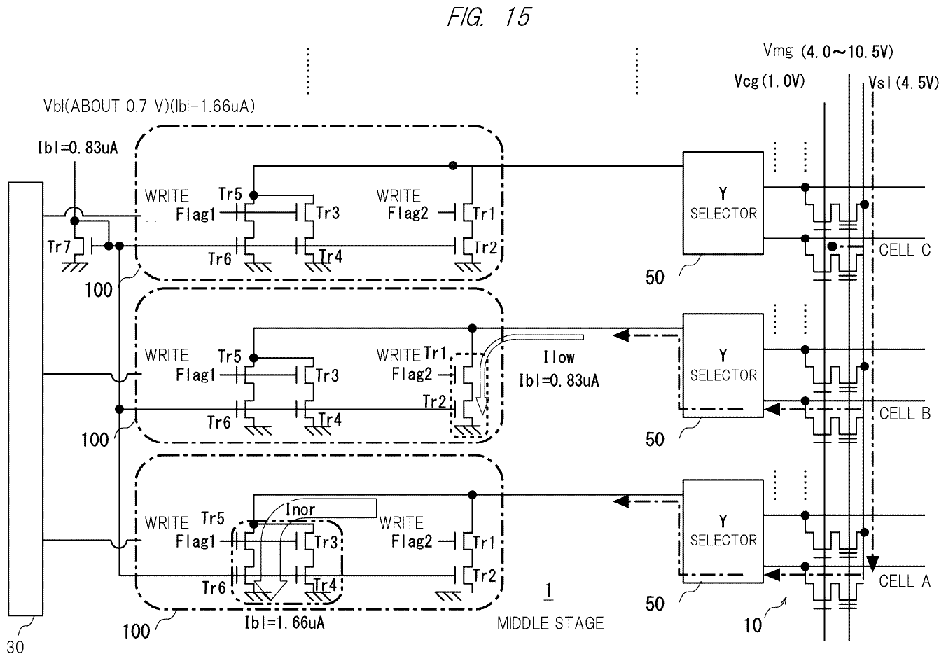

FIG. 14 is a graph for explaining a writing operation at a middle stage of the writing, and FIG. 15 is a circuit diagram for explaining the writing operation at the middle stage of the writing. At the middle stage of the writing, the Vmg voltage is further gradually raised, and the cell (that is the cell B in FIG. 14) having the cell voltage Vt exceeding the verify level B appears. Note that the cell voltage Vt of the cell C has exceeds the verify level A, and therefore, the writing is ended. As illustrated in the circuit diagram of FIG. 15, for the cell A, the write bit line current control circuit 100 performs control to make flow of the normal write current Inor (Ibl=1.66 μA) through the transistors Tr3 and Tr4 and the transistors Tr5 and Tr6 when the gate voltage exceeding the threshold voltage is applied as the write Flag 1 at the time of the normal writing. For the cell B, the write bit line current control circuit 100 performs control to make flow of the low-speed write current Ilow (Ibl=0.83 μA) through the transistors Tr1 and Tr2 when the gate voltage exceeding the threshold voltage is applied as the write Flag 2 at the time of the low-speed writing. For the cell C, the writing has been ended, and therefore, the write bit line current control circuit 100 does not make the flows of the normal write current Inor (Ibl=1.66 μA) and the low-speed write current Ilow (Ibl=0.83 μA) therethrough.

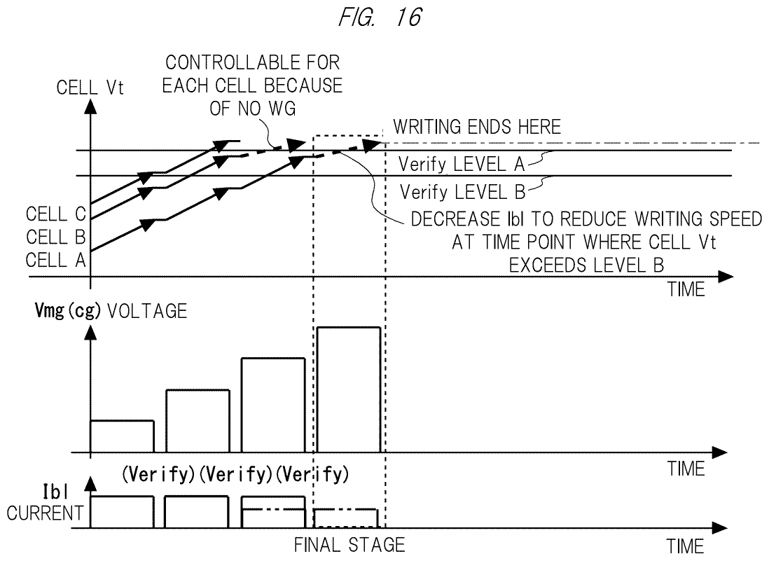

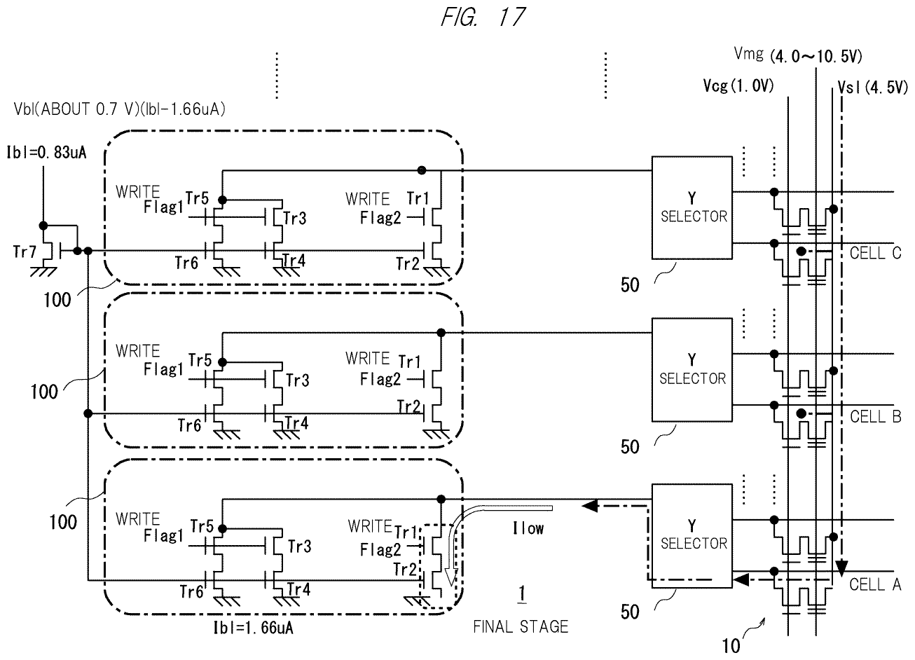

FIG. 16 is a graph for explaining a writing operation at a final stage of the writing, and FIG. 17 is a circuit diagram for explaining the writing operation at the final stage of the writing. At the final stage of the writing, the Vmg voltage is gradually raised, and respective cell voltages Vt of almost all of cells exceed the verify level B (FIG. 16). As illustrated in FIG. 17, for the cell A, the write bit line current control circuit 100 performs control to make flow of the low-speed write current Ilow (Ibl=0.83 μA) through the transistors Tr1 and Tr2 when the gate voltage exceeding the threshold voltage is applied as the write Flag 2 at the time of the low-speed writing. For the cells B and C, respective cell voltages Vt of the cells B and C exceed the verify level A, and the writing has been ended, and therefore, each of the write bit line current control circuits 100 does not make the flows of the normal write current Inor (Ibl=1.66 μA) and the low-speed write current Ilow (Ibl=0.83 μA) therethrough.

For all the cells (cells A, B, and C), when the respective cell voltages exceed the verify level A, all the write bit line current control circuits 100 each stop the current, and the writing is ended.

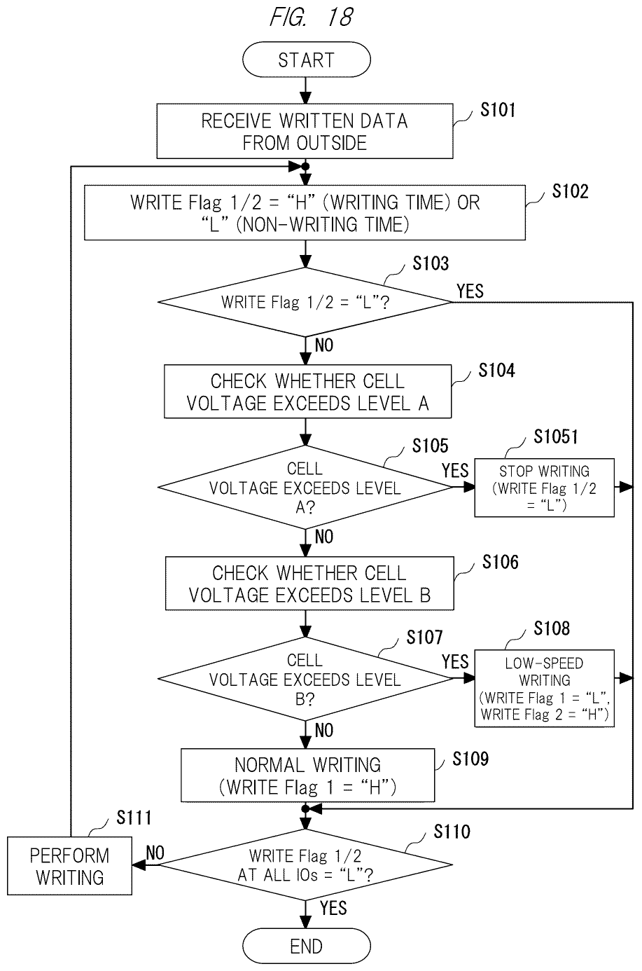

FIG. 18 is a flowchart of distribution-narrowed writing. The flowchart can be executed by at least one of the control circuits 5 (FIG. 9) that control an operation of the entire circuit. The control circuit 5 receives data to be written into each of memory cells from outside (step S101). For each of the memory cells, the control circuit 5 checks whether the write Flag 1 is “H” (at the time of writing) or “L” (at the time of non-writing) while the write Flag 2 is “H” (at the time of writing) or “L” (at the time of non-writing) (step S102). If the write Flag 1 is “H” (at the time of writing) while the write Flag 2 is “H” (at the time of writing) (“NO” in step S102), the control circuit 5 checks whether or not its cell voltage exceeds the verify level A, on the basis of the reading result of each of the memory cells (step S104). If the cell voltage does not exceed the verify level A (“NO” in step S105), the control circuit 5 checks whether or not the cell voltage exceeds the verify level B, on the basis of the reading result of each of the cells (step S106). On the other hand, if the cell voltage exceeds the verify level A (“YES” in step S105), the control circuit 5 sets both the write Flag 1 and the write Flag 2 to “L” (at the time of non-writing) (step S1051). As a result, the writing into the cell is stopped.

If the cell voltage exceeds the level B (“YES” in step S107), the write Flag 2 is “H” (at the time of writing) while the write Flag 1 is “L” (at the time of non-writing). The control circuit 5 causes the write bit line current control circuit 100 to make flow of the low-speed write current through the bit line to the corresponding cell to perform the low-speed writing (step S108). On the other hand, if the cell voltage does not exceed the level B (“NO” in step S107), the write Flag 1 is “H” (at the time of writing). The control circuit 5 causes the write bit line current control circuit 100 to make flow of the normal write current through the bit line to the corresponding cell to perform the normal writing (step S109). If the write data 2 or 1 in all IOs is “L” (at the time of non-writing) (“YES” in step S110), the processing ends. On the other hand, if the write data 2 or 1 in all IOs is not “L” (at the time of non-writing) (that is, any one is “H” (at the time of writing) (“NO” in step S110), the writing operation is performed (step S111), and the processing 25 from step S102 to step S110 is repeated.

In the embodiment described above, the distribution of the cell voltage Vt can be narrowed. Further, the present disclosure is also applicable to high-speed writing as described below. The plurality of memory cells can include at least one of the multiple level cell (MLC), the triple level cell (TLC), and the quad level cell (QLC).

### OTHER EMBODIMENTS

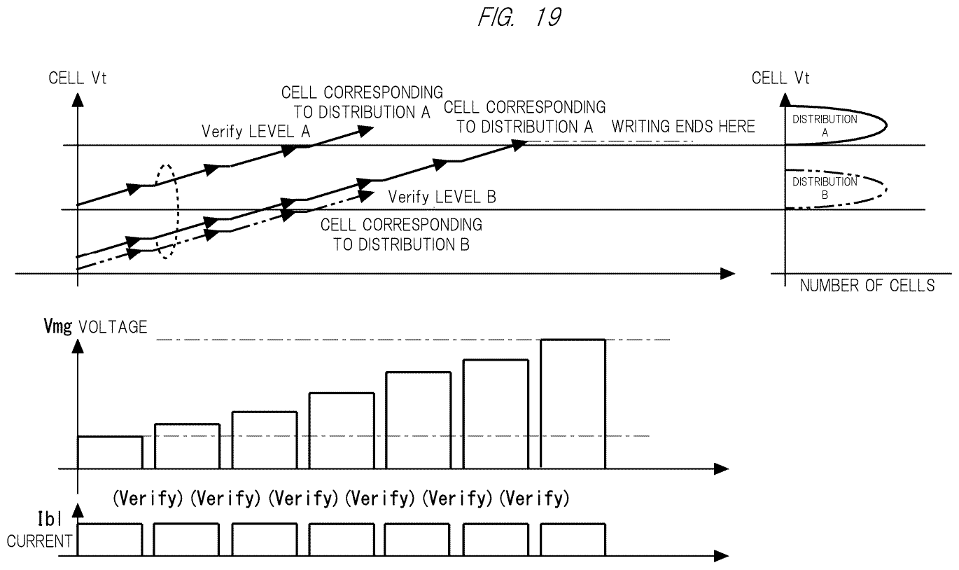

FIG. 19 is a diagram for explaining the general multi-bit writing according to another embodiment. In a case of the general MLC, in order to simultaneously write a plurality of cell voltage levels, a writing start voltage is started to match a distribution “B” corresponding to the verify level B lower than the verify level A representing the end of the writing. This needs to be started from the relatively low Vmg voltage. Accordingly, it takes long until writing of a distribution “A” corresponding to the verify level A representing the end of the writing is ended.

Accordingly, in the present embodiment, the write current Ibl is made controllable for each of target distributions corresponding to the memory cells by the write bit line current control circuit 100 that is the same as that of the above-described embodiment to achieve the high-speed writing operation.

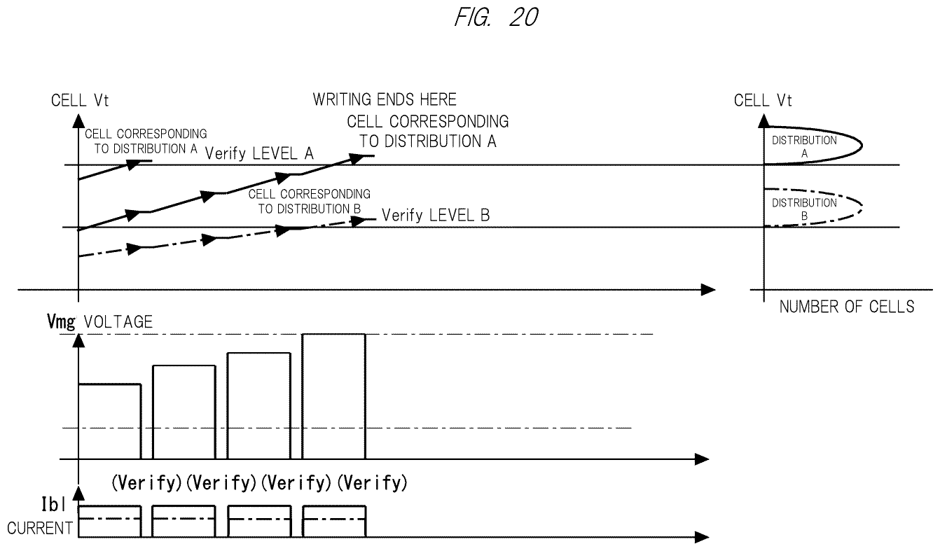

FIG. 20 is a graph for explaining the writing operation according to another embodiment. For the cell (such as the cell A or the cell C) corresponding to the distribution A, the normal write current Inor (Ibl=1.66 μA) is set to achieve the normal writing speed. On the other hand, for the cell (such as the cell B) corresponding to the distribution B having the lower cell voltage level than that of the distribution A, the low-speed write current Inor (Ibl=0.83 μA) is set to achieve the low-speed writing speed. Note that, for example, the distribution A may correspond to the “01” write cell illustrated in FIG. 3 while the distribution B may correspond to the “10” write cell illustrated in FIG. 3.

As a result, the Vmg voltage at the writing start can be set relatively higher than that in the case illustrated in FIG. 19, and the number of times of the writing retry can be decreased to increase the speed of the writing operation.

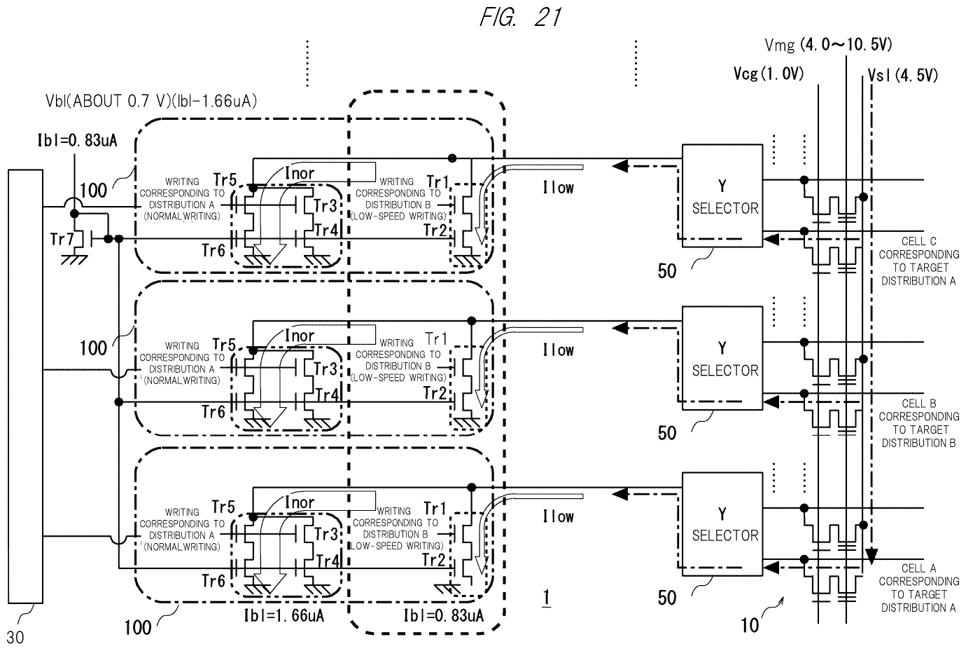

FIG. 21 is a circuit diagram for explaining the writing operation according to the present embodiment. The circuit diagram of FIG. 21 is similar to the circuit diagram of FIG. 10 or the like. However, in the above-described embodiment, either the normal write current or the low-speed write current can be selected depending on a target distribution that differs for each of the memory cells, without the change of the writing speed during the processing as described in the present embodiment.

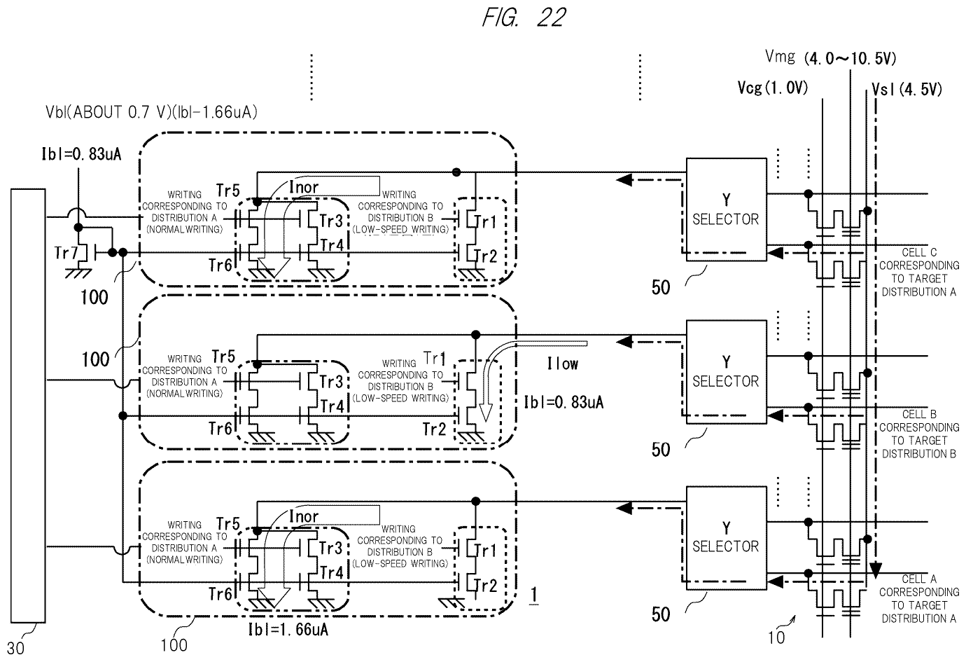

FIG. 22 is a circuit diagram for explaining the writing operation according to the present embodiment. For the cell A or the cell C corresponding to the distribution A, the normal write current Inor (Ibl=1.66 μA) is set to achieve the normal writing speed. On the other hand, for the cell B corresponding to the distribution B having the lower cell voltage level than that of the distribution A, the low-speed write current Inor (Ibl=0.83 μA) is set to achieve the low-speed writing speed.

As illustrated in FIG. 22, for the cell A, the write bit line current control circuit 100 performs control to make flow of the normal write current Inor (Ibl=1.66 μA) through the transistors Tr3 and Tr4 and the transistors Tr5 and Tr6 when the gate voltage exceeding the threshold voltage is applied as the normal writing corresponding to the distribution A. Similarly, for the cell C, the write bit line current control circuit 100 performs control to make flow of the normal write current Inor (Ibl=1.66 μA) through the transistors Tr3 and Tr4 and the transistors Tr5 and Tr6 when the gate voltage exceeding the threshold voltage is applied at the time of the normal writing corresponding to the distribution A.

On the other hand, for the cell B, the write bit line current control circuit 100 performs control to make flow of the low-speed write current Ilow (Ibl=0.83 μA) through the transistors Tr1 and Tr2 when the gate voltage exceeding the threshold voltage is applied as the low-speed writing corresponding to the distribution B.

For the cells A, B, and C, the same Vmg voltage is gradually raised and applied as illustrated in FIG. 20. In this case, the Vmg voltage at the start can be set higher than that in the comparative example illustrated in FIG. 19, and therefore, the writing operation can be ended in a short time.

In some embodiments, note that flow of a normal write current corresponding to a target distribution A may be made for the cell A, flow of a middle-speed write current corresponding to a target distribution B may be made for the cell B, and flow of a low-speed write current corresponding to a target distribution C may be made for the cell C. In this case, in the write bit line current control circuit, a circuit for the normal write current, a circuit for the middle-speed write current, and a circuit for the low-speed write current may be arranged in parallel. In this case, in the circuit for the normal write current, at least three transistors may be arranged in parallel. In the circuit for the middle-speed write current, at least two transistors may be arranged in parallel. In the circuit for the low-speed write current, at least one transistor may be arranged in parallel. Thus, the present disclosure is also applicable to an n-bit (“n” is an optional integer) MLC cell such as a TLC or a QLC as can be appreciated by those skilled in the art.

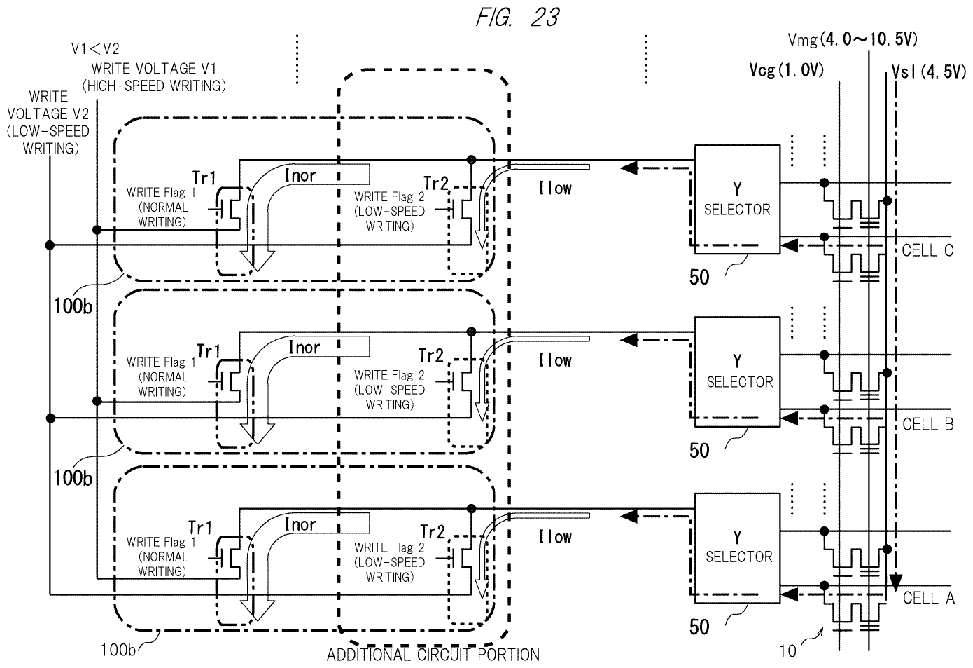

FIG. 23 is a circuit diagram including a write bit line voltage control circuit according to another embodiment. The write bit line current control circuit 100 described in FIG. 10 or the like can also be replaced with a write bit line voltage control circuit 100b illustrated in FIG. 23. A basic operation principle is similar to that in the embodiment described in FIG. 10 or the like.

The bit line bl coupled to the Y selector 50 is connected to the transistor Tr2 used for the current (“Inor” in FIG. 11) at the time of the normal writing. A write voltage V1 is applied to a source electrode of the transistor Tr2. When the gate voltage exceeding the threshold voltage is applied as the write Flag 1 at the time of the normal writing, the normal write current Inor flows through the transistor Tr2.

On the other hand, the bit line bl coupled to the Y selector 50 is connected to the transistor Tr1 used for the current (“Ilow” in FIG. 11) at the time of the low-speed writing. A write voltage V2 is applied to a source electrode of the transistor Tr1. In the write bit line current control circuit 100b, the write voltage V1 used for the normal writing is controlled to be lower than the write voltage V2 used for the low-speed writing. When the gate voltage exceeding the threshold voltage is applied as the write Flag 2 at the time of the low-speed writing, the low-speed write current Ilow flows through the transistor Tr2.

According to some embodiments, a semiconductor nonvolatile memory device can be provided. In the semiconductor nonvolatile memory device including: a plurality of gate lines; a plurality of bit lines respectively intersecting the plurality of gate lines; and a plurality of memory cells connected to respectively intersection points between the gate lines and the bit lines, the plurality of memory cells are connected to one gate line selected from among the plurality of gate lines respectively via the different bit lines, and the semiconductor nonvolatile memory device further includes a plurality of write bit line current or voltage control circuits respectively controlling bit line currents in order to simultaneously perform writing into the plurality of memory cells. In another embodiment, the semiconductor nonvolatile memory device may be configured such that a plurality of cell voltage verify levels for checking cell states are respectively provided for a plurality of target cell voltage distributions, and such that the write bit line current or voltage control circuits respectively control writing speeds by using the plurality of bit line currents selected on the basis of a plurality of gate voltages and reading results corresponding to the verify levels. The semiconductor nonvolatile memory device may be configured such that a first cell voltage verify level representing end of the cell writing and a second cell voltage verify level lower than the first cell voltage verify level are respectively provided target cell voltage distributions, and such that, if it is verified from a reading result of a memory cell that the cell voltage exceeds the second cell voltage verify level, the write bit line current or voltage control circuit controls a write bit line current of the memory cell to a current lower than the normal current.

In still another embodiment, the write bit line current control circuit 100 can include: a first transistor Tr4 and a second transistor Tr6 each having a gate receiving a reference potential and being connected in parallel to each other to pass a first write bit line current; and a third transistor Tr2 having a gate receiving a reference potential and passing a second write bit line current smaller than the first write bit line current (see FIG. 11). Further, the write bit line current control circuit 100 can include: a fourth transistor Tr3 and a fifth transistor Tr5 each having a gate receiving a write flag signal and being connected in series to the first transistor Tr4 and the second transistor Tr6 respectively; and a sixth transistor Tr1 having a gate receiving a write flag signal and being directly connected to the third transistor Tr2 (see FIG. 11).

The write bit line voltage control circuit 100b may include: a first transistor Tr1 having a gate receiving a first write flag signal and a source receiving a write voltage and passing a first write bit line current; and a second transistor Tr2 having a gate receiving a second write flag signal and a source receiving a write voltage and passing a second write bit line current smaller than the first write bit line current, and a source potential V1 of the first transistor Tr1 may be controlled to be lower than a source potential V2 of the second transistor Tr2 (see FIG. 23).

In still another embodiment, the semiconductor nonvolatile memory device may include: a first Y selector selecting one gate line of a plurality of gate lines; a second Y selector selecting one gate line of the plurality of gate lines; and a third Y selector selecting one gate line of the plurality of gate lines, and may include a first write bit line current or voltage control circuit, a second write bit line current or voltage control circuit, and a third write bit line current or voltage control circuit respectively corresponding to the first Y selector, the second Y selector, and the third Y selector.

A pulse voltage may be applied a plurality of times to respective gate electrodes of the plurality of memory cells via gate lines, the pulse voltage may be applied thereto the plurality of times while gradually increasing, and verify periods during which verifying is performed may be respectively provided among the plurality of times of application of the pulse voltage. The plurality of memory cells can include at least one of a multiple level cell (MLC), a triple level cell (TLC), and a quad level cell (QLC).

In the foregoing, the invention made by the inventors of the present application has been concretely described on the basis of the embodiments. However, the present invention is not limited to the foregoing embodiments, and various modifications can be made within the scope of the present invention.

What is claimed is:

1. A semiconductor nonvolatile memory device comprising:
a plurality of gate lines;
a plurality of bit lines respectively intersecting the plurality of gate lines; and
a plurality of memory cells connected to respectively intersection points between the gate lines and the bit lines,
wherein the plurality of memory cells are connected to one gate line selected from among the plurality of gate lines respectively via the different bit lines, and
the semiconductor nonvolatile memory device further includes a plurality of write bit line current or voltage control circuits respectively controlling bit line currents in order to simultaneously perform writing into the plurality of memory cells.

2. The semiconductor nonvolatile memory device according to claim 1,
wherein a plurality of cell voltage verify levels for checking cell states are respectively provided for a plurality of target cell voltage distributions, and
the write bit line current or voltage control circuits respectively control writing speeds by using the plurality of bit line currents selected on the basis of a plurality of gate voltages and reading results corresponding to the verify levels.

3. The semiconductor nonvolatile memory device according to claim 2,
wherein a first cell voltage verify level representing end of cell wiring and a second cell voltage verify level lower than the first cell voltage verify level are provided for the target cell voltage distributions, and,
if it is verified from a reading result of a memory cell that the cell voltage exceeds the second cell voltage verify level, the write bit line current or voltage control circuit controls a write bit line current of the memory cell to a current lower than a normal current.

4. The semiconductor nonvolatile memory device according to claim 2,
wherein the write bit line current control circuit includes:
a first transistor and a second transistor each having a gate receiving a reference potential and being connected in parallel to each other to pass a first write bit line current; and
a third transistor having a gate receiving a reference potential and passing a second write bit line current smaller than the first write bit line current.

5. The semiconductor nonvolatile memory device according to claim 4,
wherein the write bit line current control circuit includes:
a fourth transistor and a fifth transistor each having a gate receiving a write flag signal and being connected in series to the first transistor and the second transistor respectively; and
a sixth transistor having a gate receiving a write flag signal and being directly connected to the third transistor.

6. The semiconductor nonvolatile memory device according to claim 2,
wherein the write bit line voltage control circuit includes:
a first transistor having a gate receiving a first write flag signal and a source receiving a write voltage and passing a first write bit line current; and
a second transistor having a gate receiving a second write flag signal and a source receiving a write voltage and passing a second write bit line current smaller than the first write bit line current, and
a source potential of the first transistor is controlled to be lower than a source potential of the second transistor.

7. The semiconductor nonvolatile memory device according to claim 1,
wherein a pulse voltage is applied a plurality of times to respective gate electrodes of the plurality of memory cells via the gate lines,
the pulse voltage is applied the plurality of times while gradually increasing, and
verify periods during which verifying is performed are respectively provided among the plurality of times of application of the pulse voltage.

8. The semiconductor nonvolatile memory device according to claim 1,
wherein the plurality of memory cells include an n-bit (n is an optional integer) multiple level cell (MLC), that is, include at least one of a triple level cell (TLC) and a quad level cell (QLC).
